(19) United States
(12) Patent Application Publication
(10) Pub. No.: US 2016/0218261 A1
(43) Pub. Date: Jul. 28, 2016

(54) OPTOELECTRONIC SEMICONDUCTOR COMPONENT AND METHOD OF FABRICATING AN OPTOELECTRONIC SEMICONDUCTOR COMPONENT

(71) Applicant: OSRAM OPTO SEMICONDUCTORS GMBH, Regensburg (DE)

(72) Inventors: Jürgen Moosburger, Lappersdorf (DE); Ion Stoll, Tegernheim (DE); Thomas Schwarz, Regensburg (DE); Frank Singer, Regenstauf (DE); Georg Dirscherl, Tegernheim (DE); Lutz Höppel, Alteglofsheim (DE)

(21) Appl. No.: 15/021,091

(22) PCT Filed: Aug. 25, 2014
(86) PCT No.: PCT/EP2014/068000

§ 371 Date: Mar. 10, 2016

(30) Foreign Application Priority Data
Sep. 13, 2013 (DE) 10 2013 110 114.3

(51) Int. Cl. H01L 33/60; H01L 33/56

(52) U.S. Cl. CPC H01L 33/60; H01L 33/56; H01L 2933/0091; H01L 2933/005; H01L 2933/0058

(57) ABSTRACT

An optoelectronic semiconductor component includes an optoelectronic semiconductor chip including a light-transmissive carrier, a semiconductor layer sequence on the light-transmissive carrier and electrical connection points on a bottom portion remote from the light-transmissive carrier of the semiconductor layer sequence, a light-transmissive encapsulating material enclosing the optoelectronic semiconductor chip in places, and particles of a light-scattering and/or light-reflecting material, wherein the bottom of the semiconductor layer sequence is at least in places free of the light-transmissive encapsulating material, and the particles cover the bottom of the semiconductor layer sequence and an outer face of the encapsulating material in places.

### TECHNICAL FIELD

This disclosure relates to an optoelectronic semiconductor component and a method of producing an optoelectronic semiconductor component.

### BACKGROUND

U.S. Pat. No. 7,271,425 describes an optoelectronic semiconductor component. It could nonetheless be helpful to provide an optoelectronic semiconductor component that is particularly simple to produce.

### SUMMARY

We provide an optoelectronic semiconductor component including an optoelectronic semiconductor chip including a light-transmissive carrier, a semiconductor layer sequence on the light-transmissive carrier and electrical connection points on a bottom portion remote from the light-transmissive carrier of the semiconductor layer sequence, a light-transmissive encapsulating material enclosing the optoelectronic semiconductor chip in places, and particles of a light-scattering and/or light-reflecting material, wherein the bottom of the semiconductor layer sequence is at least in places free of the light-transmissive encapsulating material, and the particles cover the bottom of the semiconductor layer sequence and an outer face of the encapsulating material in places.

We also provide a method of producing an optoelectronic semiconductor component including providing an optoelectronic semiconductor chip comprising a light-transmissive carrier, a semiconductor layer sequence on the light-transmissive carrier and electrical connection points on a bottom portion remote from the light-transmissive carrier of the semiconductor layer sequence, applying the optoelectronic semiconductor chip onto an auxiliary carrier such that the electrical connection points face the auxiliary carrier, encapsulating the optoelectronic semiconductor chip in a light-transmissive encapsulating material, wherein the light-transmissive encapsulating material on the bottom portion thereof adjoins the auxiliary carrier, detaching the auxiliary carrier and exposing the bottom portion of the semiconductor layer sequence and the light-transmissive encapsulating material, and applying particles of a light-scattering and/or light-reflecting material to the exposed bottom portion of the semiconductor layer sequence and the encapsulating material.

We further provide an optoelectronic semiconductor component including an optoelectronic semiconductor chip including a light-transmissive carrier, a semiconductor layer sequence on the light-transmissive carrier and electrical connection points on a bottom portion remote from the light-transmissive carrier of the semiconductor layer sequence, a light-transmissive encapsulating material that encloses the optoelectronic semiconductor chip in places, and particles, wherein the bottom portion of the semiconductor layer sequence is at least in places free of the light-transmissive encapsulating material, the particles cover the bottom portion of the semiconductor layer sequence and an outer face of the encapsulating material in places, the particles are fixed by a material with good gap penetration on the bottom portion of the semiconductor layer sequence and the outer face of the encapsulating material, wherein the material with good gap penetration is in places in direct contact with at least some of the particles and the encapsulating material, the particles form a layer, and the material with good gap penetration penetrates completely through the layer of particles and the encapsulating material differs from the material with good gap penetration.

### BRIEF DESCRIPTION OF THE DRAWINGS

FIGS. 1A to 1F schematically show a first example of our method.

FIGS. 2A to 2F schematically show views of a second example of our method.

FIGS. 3 and 4 schematically show examples of optoelectronic semiconductor components.

FIGS. 5A to 5F schematically show a third example of our method.

### LIST OF REFERENCE NUMERALS

1 Optoelectronic semiconductor chip
10 Light-transmissive carrier
11 Semiconductor layer sequence
12 Electrical connection point
2 Auxiliary carrier
21 Main body of auxiliary carrier
22 Releasable bonding agent
3 Light-transmissive encapsulating material
4 Reflective layer
41 Particles
42 Material with good gap penetration
5 Electrically conductive material
6 Separation region
7 Solder resist lacquer
8 ESD-protective layer
9 ESD-protective element
91 Electrical connection points

### DETAILED DESCRIPTION

Our optoelectronic semiconductor component is, for example, a light-emitting diode that emits light when in operation. The optoelectronic semiconductor component may in particular be provided for surface mounting and the optoelectronic semiconductor component may then in particular be a surface-mountable component (SMD: Surface Mounted Device).

The optoelectronic semiconductor component may comprise an optoelectronic semiconductor chip. The optoelectronic semiconductor chip comprises, for example, a light-emitting diode chip. The optoelectronic semiconductor chip comprises in particular a light-transmissive carrier, a semiconductor layer sequence on the light-transmissive carrier and electrical connection points on the bottom remote from the light-transmissive carrier of the semiconductor layer sequence.

The light-transmissive carrier of the optoelectronic semiconductor chip may in particular be a growth substrate for the semiconductor layer sequence. The light-transmissive carrier may then, for example, be formed with glass, sapphire or SiC or consist of one of these materials. The semiconductor layer sequence is grown epitaxially on the light-transmissive carrier and comprises at least one active region that generates or detects electromagnetic radiation. The optoelectronic semiconductor chip comprises electrical connection points on the bottom remote from the light-transmissive carrier of the semiconductor layer sequence.

In particular, it is possible for the optoelectronic semiconductor chip to have electrical connection points only on the bottom. The optoelectronic semiconductor chip may then be mounted, for example, in the manner of a “flip chip.” The optoelectronic semiconductor chip is preferably free in particular of a metallic reflector layer, which could be arranged, for example, on the bottom remote from the light-transmissive carrier of the semiconductor layer sequence. In other words, the optoelectronic semiconductor chip does not comprise any in particular metallic mirror with which electromagnetic radiation which is radiated in the direction of the bottom of the semiconductor layer sequence may be reflected towards the transmissive carrier. The optoelectronic semiconductor chip is thus free of an in particular metallic reflector and therefore particularly simple and inexpensive to produce. It is, however, possible for a dielectric mirror to be arranged in places on the bottom of the semiconductor layer sequence.

The electromagnetic radiation generated in the optoelectronic semiconductor chip or the light generated in the optoelectronic semiconductor chip exits if the optoelectronic semiconductor chip is, for example, a light-emitting diode, through the light-transmissive carrier. The electromagnetic radiation or the light may exit through the top of the light-transmissive carrier remote from the semiconductor layer sequence and through side faces of the light-transmissive carrier. The optoelectronic semiconductor chip is then a so-called “volume” emitter rather than a surface emitter.

The electrical connection points of the optoelectronic semiconductor chip may be formed with a radiation-transmissive material such as, for example, a TCO (Transparent Conductive Oxide), i.e., a light-transmissive oxide. The electrical connection points are, for example, formed with or from ITO such that no or barely any reflection of light towards the light-transmissive carrier takes place even at the electrical connection points.

The optoelectronic semiconductor component may comprise a light-transmissive encapsulating material that encloses the optoelectronic semiconductor chip in places. The light-transmissive encapsulating material is, for example, formed with a silicone, an epoxy resin or a silicone-epoxide hybrid material. The light-transmissive encapsulating material surrounds the optoelectronic semiconductor chip preferably such that only the bottom of the semiconductor layer sequence, which is remote from the optoelectronic semiconductor chip, and the electrical connection points on the bottom of the semiconductor layer sequence are not covered or enclosed by light-transmissive encapsulating material. Apart from these regions of the optoelectronic semiconductor chip, the optoelectronic semiconductor chip may then be fully enclosed by the light-transmissive encapsulating material, wherein the light-transmissive encapsulating material does not have to directly adjoin the optoelectronic semiconductor chip. Rather, further layers such as, for example, conversion layers with one or more luminescent materials and/or passivation layers may be arranged between the semiconductor chip and the light-transmissive encapsulating material.

The light-transmissive encapsulating material may furthermore be filled with particles such as, for example, particles of a conversion material and/or particles of a material that lowers the coefficient of thermal expansion of the encapsulating material.

The light-transmissive encapsulating material in particular forms the package for the optoelectronic semiconductor component. In other words, the light-transmissive encapsulating material constitutes the mechanically load-bearing and supporting element of the optoelectronic semiconductor component. The light-transmissive encapsulating material does not adjoin a package made, for example, with a plastics material.

In particular, the top of the light-transmissive encapsulating material remote from the optoelectronic semiconductor chip and at least in part side faces, which extend transversely of the light exit face at the top of the light-transmissive encapsulating material, may be freely accessible from outside and are not covered by a package material.

The optoelectronic semiconductor component may comprise particles of a light-scattering and/or light-reflecting material. The particles of the light-scattering and/or light-reflective material, for example, form a layer arranged on an outer face of the light-transmissive encapsulating material. The particles are provided respectively to scatter or reflect incident electromagnetic radiation or incident light from the optoelectronic semiconductor chip. The particles at least in part replace a reflector which the optoelectronic semiconductor chip does not have. The particles are to this end preferably arranged on the outer face of the light-transmissive encapsulating material facing the bottom of the semiconductor layer sequence.

The particles may, for example, be particles formed with TiO₂, AlₓO_{y}, wherein x is, for example, 2 and y is 3, ZnO, ZrO₂, BaSO₄ or HfO₂, or consist of one of these materials. The particles have a diameter of, for example, at least 50 nm and at most 5 μm, in particular at most 300 nm.

In addition, the light-reflecting and/or light-scattering particles may reflect and/or scatter the incident light chromatically. The particles may to this end also comprise colored inorganic pigments such as oxides, sulfides, cyanides, hydroxides of transition metals or other inorganic pigments. In this way, a color appearance of the finished optoelectronic semiconductor component may be achieved which is not white but rather colored.

It is furthermore possible for the light-scattering and/or light-reflecting particles to be formed with a luminescence conversion material such as YAG, LuAG, nitride converters or the like. In this way, the particles may also be radiation-converting.

The bottom of the semiconductor layer sequence may in places be free of light-transmissive encapsulating material. At this point, the semiconductor layer sequence and the electrical connection points formed on the semiconductor layer sequence are not covered by the light-transmissive encapsulating material. However, there may also be points of the bottom covered by the light-transmissive encapsulating material. For example, after encapsulation light-transmissive encapsulating material may arrive or creep between the semiconductor chip and an auxiliary carrier and remain there as a residue (“flash”). If this residue is removed (“deflashing”), then the bottom may also be completely free of encapsulating material.

The particles of the light-scattering and/or light-reflecting material may cover the bottom of the semiconductor layer sequence and an outer face of the encapsulating material in places. The particles are applied there, for example, in a layer having, for example, a thickness of at least 500 nm and at most 5 μm. The particles are applied very densely such that they constitute a proportion by weight in the layer of at least 70 percent, for example, 80 percent and a proportion by volume in the layer of at least 45 percent, for example, 50 percent.

The optoelectronic semiconductor component may comprise an optoelectronic semiconductor chip with a light-transmissive carrier, a semiconductor layer sequence on the light-transmissive carrier and electrical connection points on the bottom remote from the light-transmissive carrier of the semiconductor layer sequence. Furthermore, the optoelectronic semiconductor component of this example comprises a light-transmissive encapsulating material that encloses the optoelectronic semiconductor chip in places and particles of a light-scattering and/or light-reflecting material. In this example, the bottom of the semiconductor layer sequence is free of the light-transmissive encapsulating material and the particles cover the bottom of the semiconductor layer sequence and an outer face of the encapsulating material in places.

A method of producing an optoelectronic semiconductor component is additionally provided. The method can be used in particular to produce an optoelectronic semiconductor component. In other words, all the features disclosed for the optoelectronic semiconductor component are also disclosed for the method and vice versa.

In the method, first, the optoelectronic semiconductor chip may be provided with the light-transmissive carrier, the semiconductor layer sequence may be provided on the light-transmissive carrier and the electrical connection points may be provided on the bottom remote from the light-transmissive carrier of the semiconductor layer sequence.

In a next method step, the optoelectronic semiconductor chip is applied to an auxiliary carrier. The auxiliary carrier may, for example, comprise part of a potting mold or an injection mold. The auxiliary carrier is preferably of rigid construction and may take the form of a flat sheet. It is additionally possible for the auxiliary carrier to have wells that accommodate at least one optoelectronic semiconductor chip. The auxiliary carrier furthermore preferably comprises on its top facing the optoelectronic semiconductor chip a releasable bonding agent, with which the optoelectronic semiconductor chip may be temporarily fastened to a main body of the auxiliary carrier. The releasable bonding agent may, for example, comprise a Revalpha film, silicone as a temporary adhesive or sucrose as a temporary adhesive.

In a next method step, the optoelectronic semiconductor chip is encapsulated with the light-transmissive encapsulating material, wherein at the bottom thereof the light-transmissive encapsulating material adjoins the auxiliary carrier and thus the releasable bonding agent. The light-transmissive encapsulating material is, for example, completely covered by the releasable bonding agent on its bottom facing the auxiliary carrier apart from those points of the releasable bonding agent which are covered by the optoelectronic semiconductor chip, and may be in direct contact with the releasable bonding agent.

In a next method step, the auxiliary carrier is detached by removing the releasable bonding agent and exposing the bottom of the semiconductor layer sequence and of the light-transmissive encapsulating material.

In a further method step, the particles of the light-scattering and/or light-reflecting material are applied to the exposed bottom of the semiconductor layer sequence and the encapsulating material. The particles are preferably applied using a method with which the particles may be applied particularly densely packed on the encapsulating material. For example, the particles may be applied using electrophoretic deposition (EPD).

The method may comprise the following steps, which may be performed in particular in the stated sequence:
providing an optoelectronic semiconductor chip comprising a light-transmissive carrier, a semiconductor layer sequence on the light-transmissive carrier and electrical connection points on the bottom remote from the light-transmissive carrier of the semiconductor layer sequence,
applying the optoelectronic semiconductor chip onto an auxiliary carrier such that the electrical connection points face the auxiliary carrier,
encapsulating the optoelectronic semiconductor chip in a light-transmissive encapsulating material, wherein the light-transmissive encapsulating material on the bottom thereof adjoins the auxiliary carrier,
detaching the auxiliary carrier and exposing the bottom of the semiconductor layer sequence and of the light-transmissive encapsulating material, and
applying particles of a light-scattering and/or light-reflecting material to the exposed bottom of the semiconductor layer sequence and the encapsulating material.

The optoelectronic semiconductor component may be particularly simply produced by the method. In the method, a volume-emitting optoelectronic semiconductor chip, for example, an optoelectronic semiconductor chip with a sapphire growth substrate, is enclosed flipped in the light-transmissive encapsulating material and embedded therein. The missing reflector of the optoelectronic semiconductor chip is replaced at least in part by the particles of the light-transmissive encapsulating material. The particles, which may in particular consist of titanium dioxide or another of the above-stated materials, are applied in a high proportion by weight onto the optoelectronic semiconductor chip and the light-transmissive encapsulating material, wherein the elevated concentration of particles brings about high reflectivities with a relatively low layer thickness. To this end, methods of applying the particles are used with which a particularly high particle packing density may be achieved.

An optoelectronic semiconductor component is advantageously obtained has a mirror formed at least in part by the particles. Such a mirror is distinguished not only by its high reflectivity, but also by its very favorable aging behavior. In contrast, for example, to a metallic mirror, which might be formed with silver, a mirror of particles of the light-scattering or light-reflecting material undergoes no or virtually no corrosion. Furthermore, production of the optoelectronic semiconductor component is particularly simple since connection of the optoelectronic semiconductor chip proceeds solely from the bottom of the optoelectronic semiconductor component and it is possible to dispense with formation of through vias and use of wire bonding. The optoelectronic semiconductor chips which may be used and the deposition method of applying the particles are inexpensive, so making possible a particularly inexpensive optoelectronic semiconductor component.

The following explanations relating to examples relate to optoelectronic semiconductor components and to methods for producing optoelectronic semiconductor components. The features and combinations of features are therefore disclosed both for the product, i.e., the optoelectronic semiconductor component, and for the method of producing the optoelectronic semiconductor component.

The particles may be fixed by a material with good gap penetration on the bottom of the semiconductor layer sequence and outer face of the encapsulating material. The material with good gap penetration may be in direct contact in places with at least some of the particles and the encapsulating material.

In other words, the particles are fixed on the bottom of the semiconductor layer sequence and of the encapsulating material by application of a material with good gap penetration. The material with good gap penetration may be, for example, an organic substance such as parylene. In addition, it may be at least one of the following materials: silicone, epoxy resin, or inorganic matrix materials such as aluminum oxide or silicon dioxide. The material with good gap penetration may be applied using an application method such as atomic layer deposition or a sol-gel method. It is moreover possible for the material with good gap penetration to be a metallic layer which then serves in contacting the optoelectronic semiconductor chip and in fixing the particles. Such a metallic layer may be applied, for example, using a gas phase process distinguished by good gap penetration.

In any event, a material with good gap penetration is used which is capable of penetrating into the interspaces between adjacent particles and in places even penetrates as far as the bottom of the semiconductor layer sequence and/or the bottom of the encapsulating material. The material with good gap penetration ensures that the particles adhere firmly to the remaining components of the optoelectronic semiconductor chip. The material with good gap penetration may itself likewise comprise reflective properties and so further increase reflectivity at the bottoms of semiconductor layer sequence and encapsulating material.

The particles may form a layer, wherein the material with good gap penetration penetrates completely through the layer of particles and the encapsulating material differs from the material with good gap penetration. The particles are arranged in one or more layers and in this way form a layer covering the bottom of the semiconductor layer sequence and an outer face of the encapsulating material in places. The material with good gap penetration penetrates right through this layer at least in places from the side thereof remote from the bottom of the semiconductor layer sequence and outer face of the encapsulating material to the bottom of the semiconductor layer sequence and to the outer face of the encapsulating material. In other words, there are paths of material with good gap penetration that penetrate completely through the layer transversely or perpendicularly to the main direction of extension thereof. The layer may be completely covered at the side thereof remote from the bottom of the semiconductor layer sequence and the outer face of the encapsulating material by the material with good gap penetration. In this way, the particles adhere particularly well to the encapsulating material and the semiconductor layer sequence.

In particular, it is in this respect also possible for the encapsulating material and the material with good gap penetration not to be the same materials, but rather to differ from one another. In this way, a material may be selected for the material with good gap penetration that penetrates particularly well through the layer of particles and that adheres particularly well to the particles.

An electrically conductive material may be arranged on the side remote from the optoelectronic semiconductor chip of the particles and/or of the material with good gap penetration, wherein the electrically conductive material electrically conductive contacts the electrical connection points of the optoelectronic semiconductor chip. The electrically conductive material is appropriately patterned such that at least two connection points are formed by the electrically conductive material on the bottom of the optoelectronic semiconductor component, via which the optoelectronic semiconductor chip of the optoelectronic semiconductor component may be contacted from the outside. The electrically conductive material may also fix the particles to the bottoms of semiconductor layer sequence and encapsulating material.

So that the electrically conductive material may come into contact with the electrical connection points of the optoelectronic semiconductor chip, these are kept free on application of the particles and/or of the material with good gap penetration and/or exposed after application.

The electrically conductive material is, for example, a highly reflective metal such as aluminum or silver. The electrically conductive material may, for example, be formed by a layer sequence of aluminum, NiV and gold, wherein the aluminum faces the semiconductor chip. Using a readily reflective material makes it possible for the layer sequence of the electrically conductive material, the particles and optionally the material with good gap penetration to have a reflectivity for light of at least 95 percent.

The electrically conductive material may in particular also serve in heat dissipation for the heat generated when the optoelectronic semiconductor chip is in operation. The electrically conductive material may, for example, be applied by electroplating or sputtering.

The particles of the light-scattering and/or light-reflecting material may be deposited by electrophoresis in an electrophoresis bath. Using electrophoresis allows the particles to be deposited particularly densely.

Prior to deposition of the particles, an electrically conductive auxiliary layer may be applied to the exposed bottom of the semiconductor layer sequence and the encapsulating material, wherein the auxiliary layer forms at least in part a salt with a protic reactant. To deposit the particles, the electrically conductive auxiliary layer is electrically contacted such that during electrophoresis charged or polarized particles of the light-scattering and/or light-reflecting material are deposited on the auxiliary layer. At least the electrically conductive auxiliary layer is introduced into the protic reactant in a next method step such that the electrically conductive auxiliary layer at least in part forms a salt with the protic reactant.

At the end of the method, for example, prior to application of the material with good gap penetration to fix the particles, the salt may be at least partially washed out by a solvent.

The electrically conductive auxiliary layer may be applied using a method such as sputtering or molecular beam epitaxy. The electrical connection points of the optoelectronic semiconductor chip may be covered by a photoresist or the layer is purposefully not deposited on the electrical connection points.

The electrically conductive auxiliary layer may have a thickness of at least 50 nm to at most 1 μm, in particular at least 150 nm and at most 500 nm, for example, of 200 nm.

The electrically conductive auxiliary layer may be formed with an electrically conductive material such as a doped semiconductor material or a metal. The electrically conductive auxiliary layer may, for example, contain one of the following materials or consist of one of the following materials: Si, Al, Ti, Ca, ZnO or GaN, wherein the stated materials may also be doped.

The photoresist applied over the electrical connection points may, for example, be removed with the overlying material prior to electrophoretic deposition, wherein a lift-off method is used. Alternatively, after deposition of the conductive material, the electrical connection points may be exposed by etching.

After deposition of the particles, the electrical connection points of the optoelectronic semiconductor chip may be re-covered with a photoresist. Then the particles may be fixed by the material with good gap penetration.

A method in which an electrically conductive auxiliary layer is used, which is then converted at least in part into a salt through introduction into a protic reactant, is described in a different context in PCT/EP2013/062618, the subject matter of which is hereby explicitly incorporated by reference.

An ESD-protective layer in electrically conductive contact with the electrically conductive material is arranged on the bottom remote from the optoelectronic semiconductor chip of the electrically conductive material. The ESD-protective layer electrically conductively contacts the electrical connection points of the optoelectronic semiconductor chip and provides ESD protection of the optoelectronic semiconductor chip, i.e., protection against electrostatic discharges. The ESD-protective layer may be formed, for example, by a varistor paste containing semiconductive particles such as SiC or ZnO particles, which form a pn junction at their abutting points. The breakdown voltage of the ESD-protective layer may be adjusted by the density of the semiconductive particles in the varistor paste. It is advantageously possible, when using the ESD-protective layer, to optionally dispense with an ESD-protective diode, which reduces material costs and manufacturing costs as well as absorption losses due to absorption of electromagnetic radiation by an ESD protection diode. Such a varistor paste is described in a different context, for example, in DE 102012207772, the subject matter of which is hereby explicitly incorporated by reference.

As an alternative or in addition to the ESD-protective layer, the optoelectronic semiconductor component may comprise an ESD-protective element applied to the auxiliary carrier prior to encapsulation with the light-transmissive encapsulating material. The ESD-protective element may, for example, be an ESD-protective diode such as a Zener diode or a varistor. The ESD-protective element may be electrically interconnected parallel or antiparallel with the optoelectronic semiconductor chip, wherein the ESD-protective element may connect electrically conductively to the optoelectronic semiconductor chip prior to encapsulation with the light-transmissive encapsulating material. However, interconnection between the optoelectronic semiconductor chip and the ESD-protective element preferably proceeds via the electrically conductive material. The ESD-protective element may be used alternatively or in addition to the ESD-protective layer, wherein when an ESD-protective layer is additionally used, an ESD-protective element with a lower protective action than is otherwise necessary may be used.

The light-transmissive encapsulating material may comprise singulation traces at least in places on the outer face thereof. The singulation traces may, for example, be traces of a sawing process or a cutting procedure. When producing the optoelectronic semiconductor component, a plurality of optoelectronic semiconductor chips may, for example, be simultaneously encapsulated with the light-transmissive encapsulating material. Production of individual optoelectronic semiconductor components may then, for example, proceed after application of the electrically conductive material by singulation into optoelectronic semiconductor components, wherein each optoelectronic semiconductor component has at least one optoelectronic semiconductor chip.

The auxiliary carrier may comprise at least one well and at least one optoelectronic semiconductor chip may be introduced into the at least one well. The side faces of the well predetermine the shape of the light-transmissive encapsulating material. In this way, the encapsulating material may, for example, comprise a base surface extending parallel to a main plane of extension of the semiconductor chip and side faces extending obliquely to the base surface depending on the shape of the well. The side faces coated with the particles then form a reflector extending obliquely relative to the base surface. The emission pattern of the optoelectronic semiconductor component may be adjusted by the angle between base surface and side face of the encapsulating material. The ESD-protective element may likewise be introduced into the well in the auxiliary carrier, wherein for each optoelectronic semiconductor chip at least one ESD-protective element may be introduced into the same well as the optoelectronic semiconductor chip.

A conductive layer may be formed on the exposed outer face of the optoelectronic semiconductor chip, which layer is applied before or after application onto the auxiliary carrier. The conductive layer may, for example, completely cover the exposed outer face of the radiation-transmissive carrier of the semiconductor chip. Contact is additionally possible between the conductive layer and the semiconductor layer sequence. The conductive layer may be electrically contacted prior to application of the light-transmissive encapsulating material, for example, via electrically conductive needles guided from the bottom of the auxiliary carrier remote from the semiconductor chip through the auxiliary carrier to the electrical connection points of the optoelectronic semiconductor chip.

The optoelectronic semiconductor chip may be electrically short-circuited via the needles. In this arrangement, it is then possible, using electrophoretic deposition, to deposit a luminescence conversion material, which may comprise one or more luminescent materials, onto the optoelectronic semiconductor chip. Once deposition is complete, the conductive layer is removed as described above by conversion into a salt and the optoelectronic semiconductor chip is encapsulated with the radiation-transmissive encapsulating material, for example, a clear silicone without further luminescence conversion material. In this configuration of the method, it is thus also possible to deposit a luminescence conversion material electrophoretically.

Alternatively, it is possible to cover the entire auxiliary carrier together with the optoelectronic semiconductor chip fastened thereto with the electrically conductive layer after application of the optoelectronic semiconductor chip to the auxiliary carrier. A photoresist is subsequently applied with patterning and a luminescence conversion material is deposited by electrophoresis at openings in the photoresist. The photoresist and electrically conductive layer are then removed.

It is moreover possible for a luminescence conversion material with one or more luminescent materials to be deposited onto the optoelectronic semiconductor chip, for example, electrophoretically and further luminescence conversion materials of one or more luminescent materials within the radiation-transmissive encapsulating material to be introduced into the light path of the optoelectronic semiconductor chip.

When electrophoretically coating the optoelectronic semiconductor chip with a luminescence conversion material, it is moreover possible for luminescence conversion materials of different luminescent materials to be applied in different layers in succession on the optoelectronic semiconductor chip.

The light-transmissive encapsulating material may comprise particles of at least one filler introduced into light-transmissive encapsulating material to adjust the refractive index, the optical behavior and/or the thermal behavior thereof. For example, particles of amorphous silicon dioxide with particle sizes of at most 100 μm, preferably of at most 50 μm may be introduced in a filler content of up to 90 weight percent, preferably up to 80 weight percent into the light-transmissive encapsulating material.

The optoelectronic semiconductor component and the method of producing an optoelectronic semiconductor component are explained in greater detail below with reference to examples and the associated figures.

Identical, similar or identically acting elements are provided with identical reference numerals in the figures. The figures and the size ratios of the elements illustrated in the figures relative to one another are not to be regarded as being to scale. Rather, individual elements may be illustrated on an exaggeratedly large scale for greater ease of depiction and/or better comprehension.

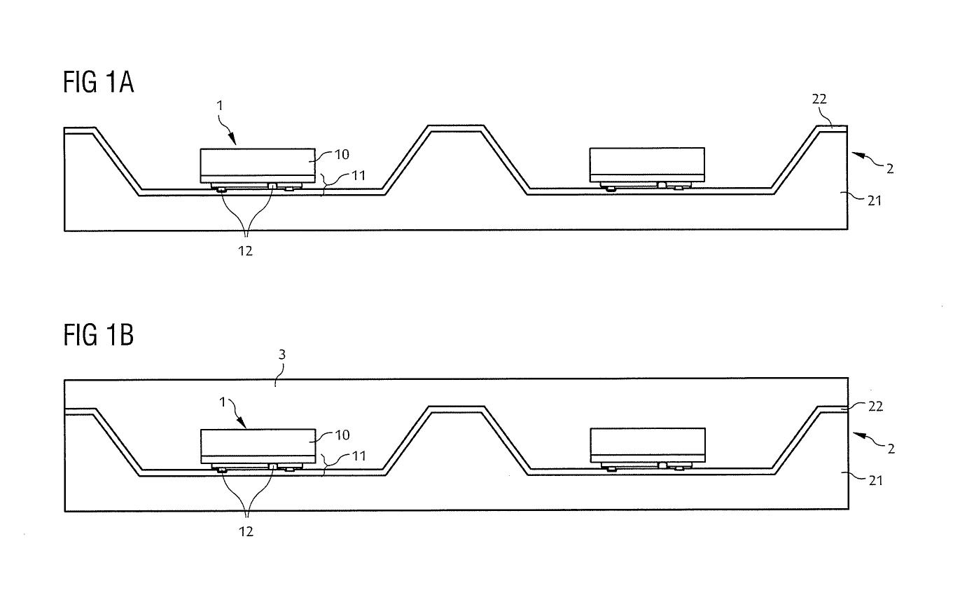

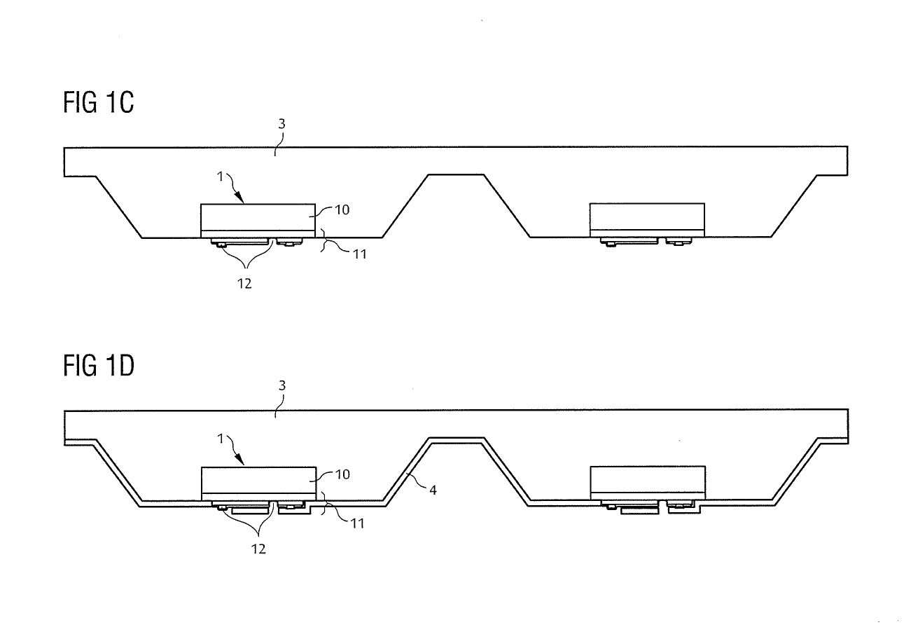

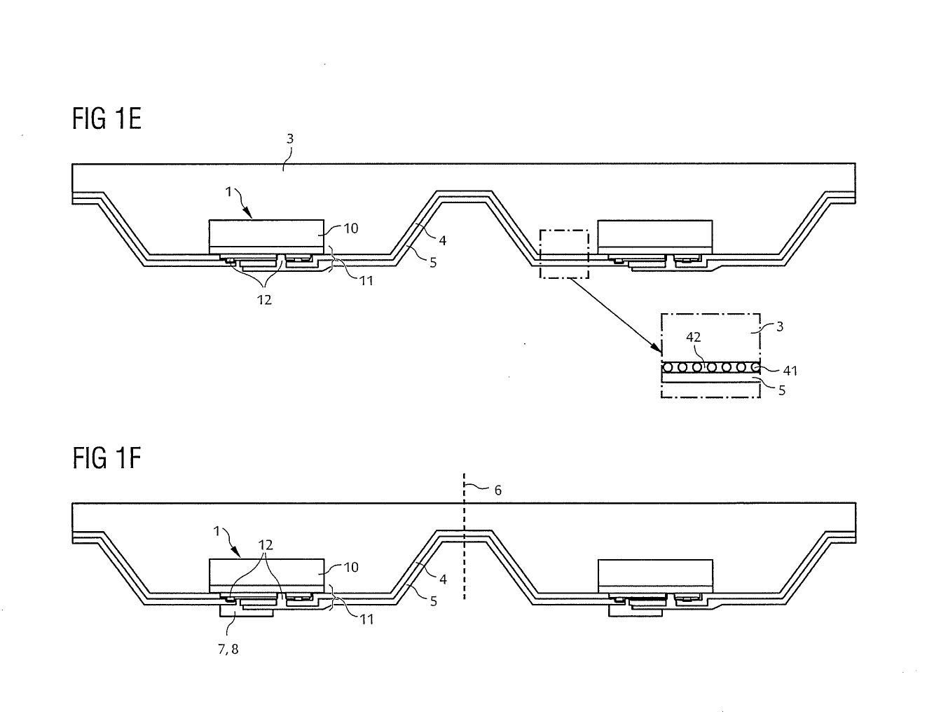

An example of a method is explained in greater detail with reference to the schematic sectional representations in FIGS. 1A to 1F.

In the method, an auxiliary carrier 2 is first provided. The auxiliary carrier 2 comprises a main body 21 formed with a rigid material such as, for example, a metal or a plastics material, and a releasable bonding agent 22 that completely covers the top of the main body 21. The releasable bonding agent is a Revalpha film, for example. This is shown in FIG. 1A.

The auxiliary carrier 2 comprises wells, one optoelectronic semiconductor chip 1 being placed into each well. The optoelectronic semiconductor chip 1 is a semiconductor chip with radiation-transmissive carrier 10 on which a semiconductor layer sequence 11 has been applied, for example, epitaxially. The light-transmissive carrier 10 may consist of sapphire, for example.

On the bottom remote from the light-transmissive carrier 10 of the semiconductor layer sequence 11, electrical connection points 12 are arranged for electrical contacting of the optoelectronic semiconductor chip. Using the electrical connection points 12, an active region in the semiconductor layer sequence 11 may, for example, be excited to generate electromagnetic radiation or light.

In a next method step, FIG. 1B, the wells of the auxiliary carrier 2 are filled with a light-transmissive encapsulating material 3, wherein the light-transmissive encapsulating material 3 is continuous over all the wells in the auxiliary carrier 2. The light-transmissive encapsulating material 3 is, for example, a highly filled silicone introduced around the semiconductor chip 1 by way of a potting process in which the auxiliary carrier 2 forms a part of the potting mold. The light-transmissive encapsulating material 3 may, for example, be filled with luminescence conversion material of one or more luminescent materials. The luminescence conversion material may, for example, be provided at least partly to absorb electromagnetic radiation generated by the optoelectronic semiconductor chip when in operation and convert it into electromagnetic radiation of a higher wavelength.

In the next method step, FIG. 1C, the auxiliary carrier 2 is detached. This leaves the optoelectronic semiconductor chips 1 encapsulated by the encapsulating material 3, wherein at least part of the bottom remote from the light-transmissive carrier 10 of the semiconductor layer sequence 11 and in particular the connection points 12 are not covered by the encapsulating material 3.

In the next method step, FIG. 1D, particles 41 of a light-scattering and/or light-reflecting material such as titanium dioxide are applied as a layer on the bottoms of the light-transmissive encapsulating material 3 and semiconductor layer sequence 11. The particles are applied electrophoretically, for example. The particles 41 are introduced in the light-reflecting layer 4, for example, in a proportion by weight of between 50 and 80 percent, wherein the thickness of the layer is, for example, 10 μm. The electrical connection points 12 of the chips may be kept free or are exposed after the end of the procedure. The particles 41 are applied electrophoretically, for example, as described above.

In a next method step, FIG. 1E, the particles 41 are first fixed by a material 42 with good gap penetration. The material 42 with good gap penetration penetrates into gaps between the particles 41 and surrounds them. It may in places be in direct contact with the light-transmissive encapsulating material 3 and the semiconductor layer sequence 11. An electrically conductive layer 5 is then applied with patterning to the bottom remote from the optoelectronic semiconductor chip 1, which layer is brought into contact with the electrical connection points 12 of the optoelectronic semiconductor chip 1.

Together with the electrically conductive material 5, the layer stack of particles 41, material 42 which readily diffuses into gaps and electrically conductive material 5 has a reflectivity of ≧95 percent. The electrically conductive material to this end contains aluminum, for example. It may, for example, be formed with a layer structure of aluminum, nickel-valadium and gold. As may be inferred in particular from the enlarged portion in FIG. 1E, the particles 41 are arranged in a layer which, in this case, comprises a layer of particles 41. The layer is completely penetrated by the material 42 with good gap penetration and is in direct contact with the encapsulating material 3 and at least in places the semiconductor body. The material 41 with good gap penetration may here in particular differ from the encapsulating material 3.

In the final method step, FIG. 1F, a layer which may be a solder resist lacquer 7 or a varistor layer 8, is applied onto the side of the electrically conductive material 5 remote from the semiconductor chip between the connection points 12. Then separation proceeds along the separation regions 6, wherein after separation optoelectronic semiconductor components are obtained, each one of which comprises at least one optoelectronic semiconductor chip.

On the finished semiconductor component, the light-transmissive encapsulating material 3 therefore comprises singulation traces from the separation procedure in the region of the separation regions 6, for example, traces of a sawing procedure.

Advantageously, in the method, it is possible to use an inexpensive sapphire chip which is in particular free of a reflector or a mirror layer on the bottom remote from the growth substrate of the semiconductor layer sequence 11. An inexpensive sapphire chip could, for example, also be mounted with the light-transmissive carrier 10 pointing towards the mounting surface, wherein the connection points 12 would then be contacted, for example, via wire contacts. In this case, the optoelectronic semiconductor chip 1 is, however, mounted inverted and the electrical connection points are contacted directly via the electrically conductive material 5, the bottom of which remote from the semiconductor chip 1 serves as a contact point to contact the optoelectronic semiconductor component. In this way, heat generated in the optoelectronic semiconductor chip may be dissipated particularly efficiently since no thermal conduction through the light-transmissive carrier 10 is needed.

In addition, the reflective layer 4 may be obtained particularly inexpensively by electrophoretic deposition of the particles 41, which may in this way be applied with a high packing density.

In addition, a plurality of optoelectronic semiconductor components may advantageously be fabricated in parallel, wherein processing, apart from introduction of the light-transmissive encapsulating material 3, may proceed entirely from the bottom of the semiconductor components.

The method may advantageously further be used to produce optoelectronic semiconductor components that taper from their radiation exit side to their mounting side. This is made possible by the wells into which the optoelectronic semiconductor chips are introduced on introduction of the light-transmissive encapsulating material. This structure of the optoelectronic semiconductor components proves particularly advantageous in surface mounting, since in this way not only is a reflector produced for the light emitted by the optoelectronic semiconductor chips towards the side during operation, but rather the shape also serves as a centering aid in surface mounting, for example, during SMD soldering since the optoelectronic component floats into position more readily due to this structure. This increases accuracy in solder mounting.

Finally, inexpensive, tried and tested methods may be used to apply luminescence conversion material of one or more luminescent materials.

Since the electrical connection points 12 are, however, formed at least in places with a radiation-transmissive material such as a TCO, it may happen that light generated in the optoelectronic semiconductor chip has to pass through the TCO material twice before it is coupled out. This may result in at least low absorption losses due to the selected design.

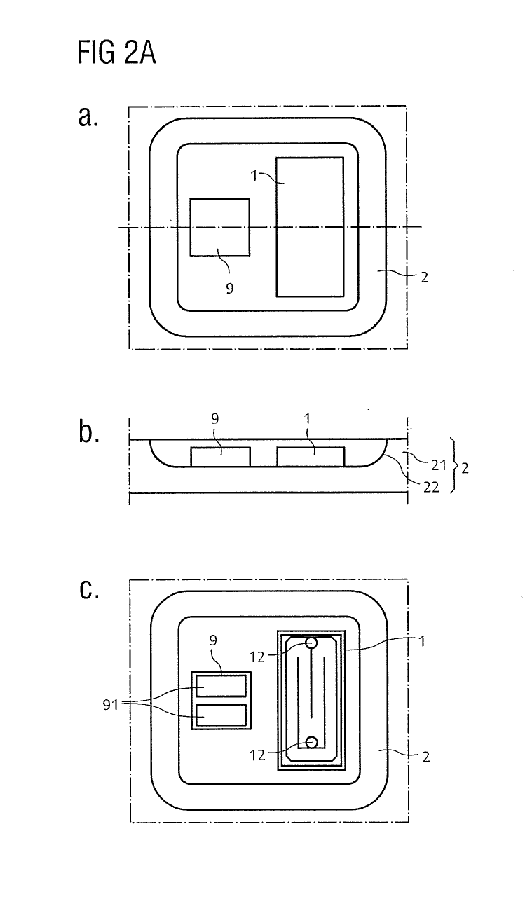

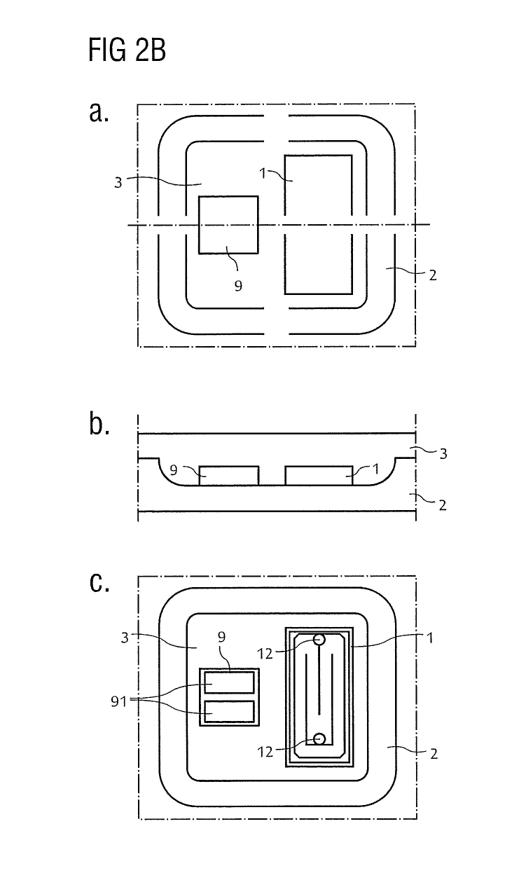

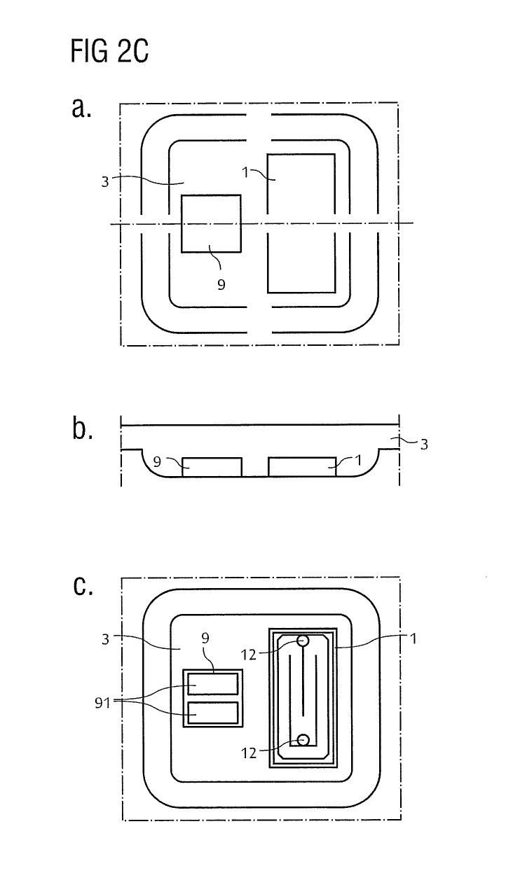

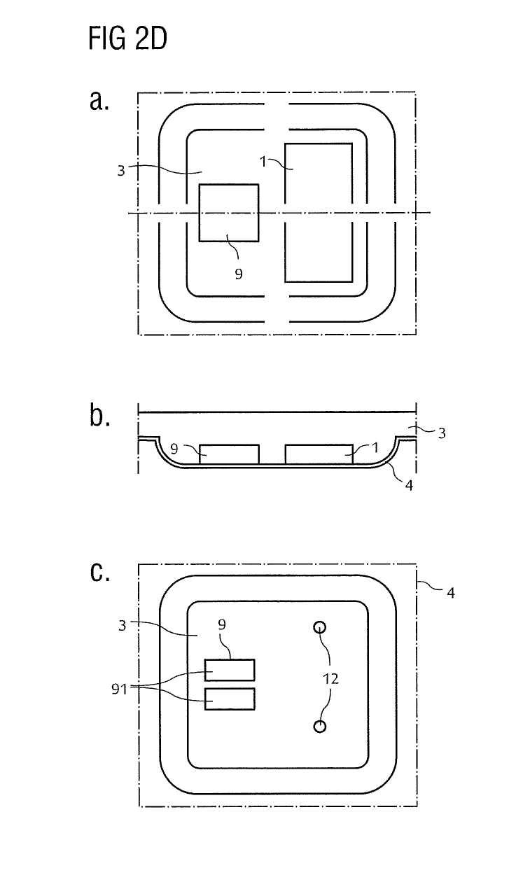

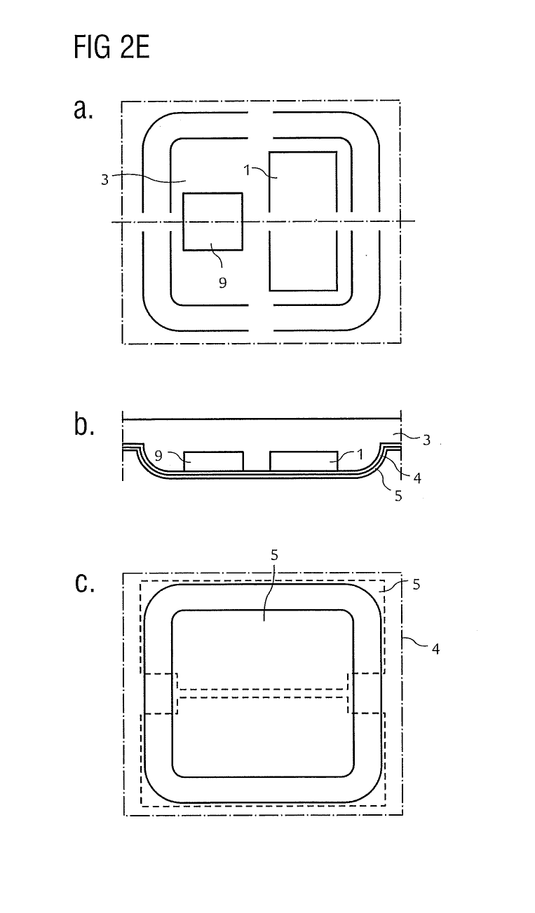

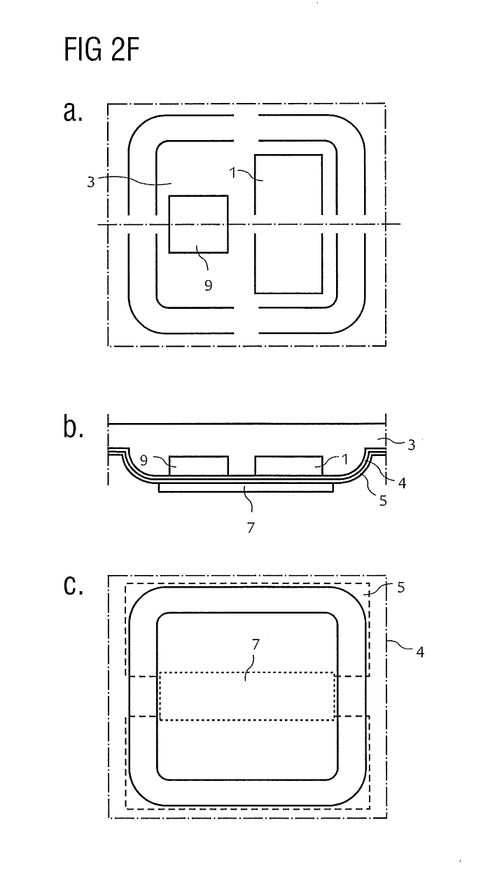

A second example of our method is explained in greater detail in conjunction with FIGS. 2A to 2F. FIGS. 2A to 2F are each subdivided into subfigures a, b and c. Subfigures a show a plan view, subfigures b a sectional representation along the broken line shown in plan view a and subfigures c show a view from below.

In contrast with the method described in conjunction with FIGS. 1A to 1F, in the method of FIGS. 2A to 2F an ESD-protective element 9 is introduced into the common well in the auxiliary carrier 2 in addition to the optoelectronic semiconductor chip 1. This is shown in FIG. 2A.

In the next method step, FIG. 2B, encapsulation with the light-transmissive encapsulating material 3 takes place. Both the optoelectronic semiconductor chip 1 and the ESD-protective element 9 are completely encapsulated by the light-transmissive encapsulating material 3 at their exposed outer faces. In this respect, at least the electrical connection points 12 of the optoelectronic semiconductor chip 1 and the electrical connection points 91 of the ESD-protective element 9 remain free of encapsulating material 3.

In the next method step, FIG. 2C, the auxiliary carrier 2 is detached.

In the following method step, FIG. 2D, the reflective layer 4 with the particles 41 is applied to the bottom of light-transmissive encapsulating material 3, ESD-protective element 9 and optoelectronic semiconductor chip 1. The reflective layer may extend to different heights at the side faces extending transversely of the base surface of the encapsulating material 3. In this way, the proportion of side emissions of the optoelectronic semiconductor component may be adjusted.

In the next method step, FIG. 2E, the electrically conductive material 5 is applied, wherein the ESD-protective element 9 and the optoelectronic semiconductor chip 1 are interconnected by the electrically conductive material 5.

In conjunction with FIG. 2F it is shown how finally a solder resist paste 7, for example, is introduced between the mutually separate regions of the electrically conductive material 5.

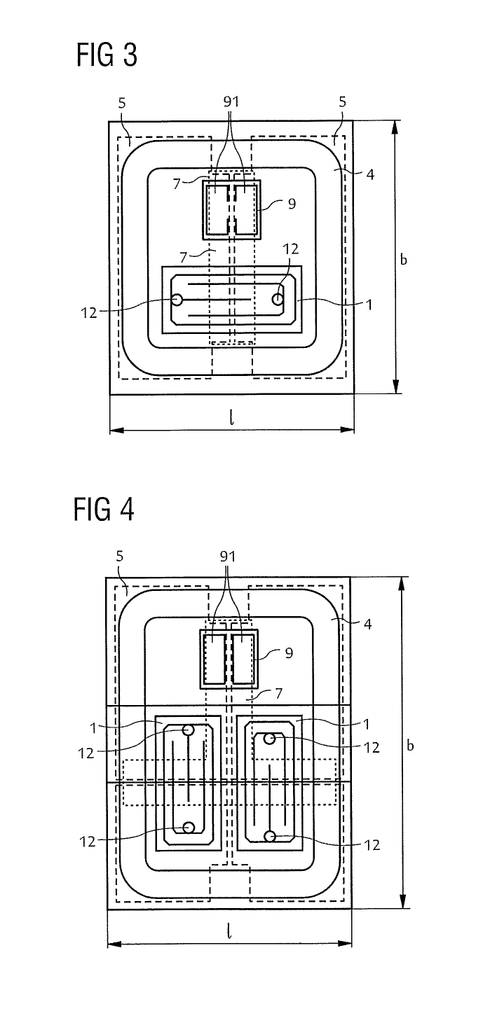

In conjunction with FIG. 3, a correspondingly produced optoelectronic semiconductor component is shown, which comprises a total chip surface area, i.e., surface area of the radiation exit face of the optoelectronic semiconductor chip 1 of, for example, 0.5 mm². The optoelectronic semiconductor component may be square or almost square. The length 1 amounts to 1.9 mm and the width b to 2 mm.

In conjunction with FIG. 4, an example of the optoelectronic semiconductor component is shown in which two identical optoelectronic semiconductor chips 1 are fitted per optoelectronic semiconductor component. This results in a chip surface area of 1 mm². The optoelectronic semiconductor component has, for example, a length 1 of 1.9 mm and a width b of 2.6 mm.

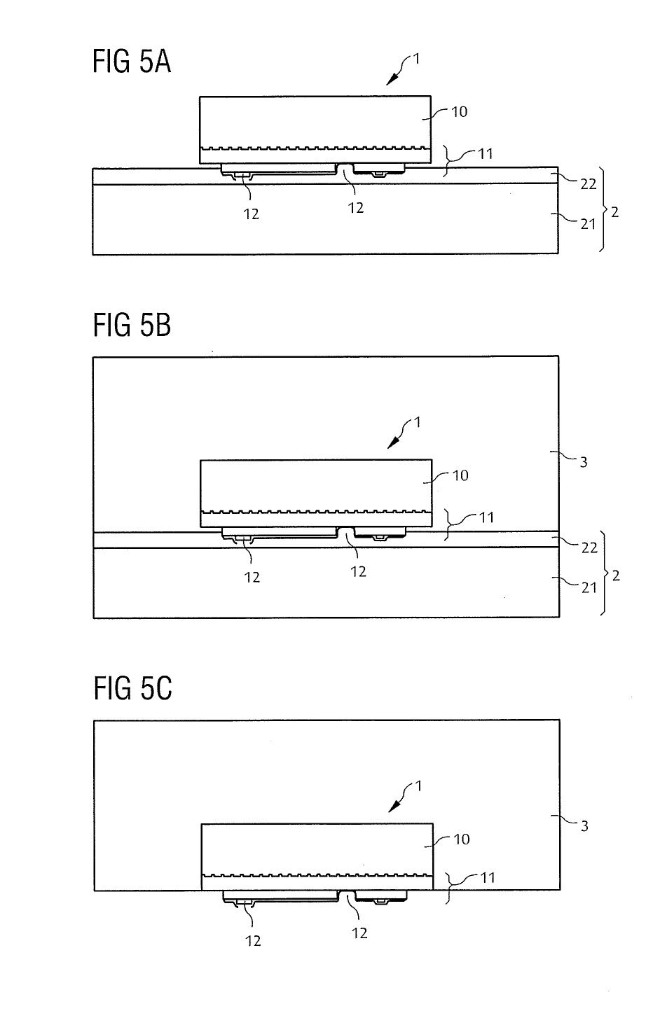

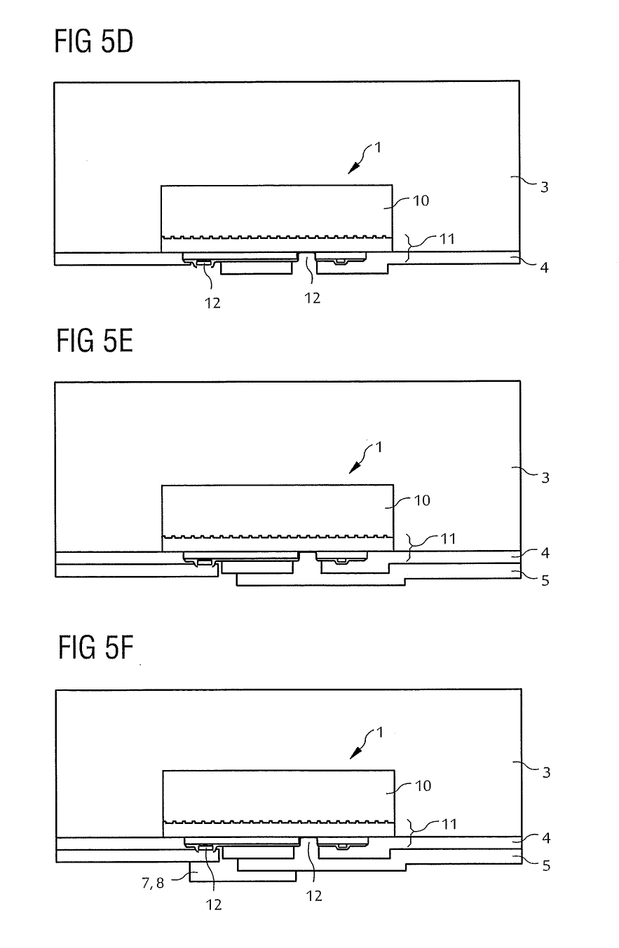

A third example of our method is explained in greater detail in conjunction with FIGS. 5A to 5F. In contrast with the example in FIGS. 1A to 1F, the auxiliary carrier 2 is not patterned in this example. Consequently, unlike, for example, in FIG. 1F, in the finished optoelectronic semiconductor component there is no reflector recess in which the semiconductor chip 1 is arranged. The method steps proceed in a manner similar to the method steps described in conjunction with FIGS. 1A to 1F.

In this way, a particularly flat component may be provided. For example, the semiconductor chip 1 has a height of 0.15 mm and the light-transmissive encapsulating material 3 has a maximum thickness of 0.4 mm. In particular, it is possible for the semiconductor chip 1 to be surrounded by the encapsulating material 3 in a thickness which is uniform within the bounds of manufacturing tolerances. In this way, if the encapsulating material 3 comprises a conversion material, particularly uniform conversion may take place in all emission directions.

Use of an ESD-protective element is also possible in this example, but not absolutely necessary.

The description made with reference to examples does not restrict our components and methods to these examples. Rather, this disclosure encompasses any novel feature and any combination of features, including in particular any combination of features in the appended claims, even if the feature or combination is not itself explicitly indicated in the claims or examples.

This application claims priority from DE 102013110114.3, the subject matter of which is hereby included by reference.

1-17. (canceled)

18. An optoelectronic semiconductor component comprising:
an optoelectronic semiconductor chip comprising a light-transmissive carrier, a semiconductor layer sequence on the light-transmissive carrier and electrical connection points on a bottom portion remote from the light-transmissive carrier of the semiconductor layer sequence;
a light-transmissive encapsulating material enclosing the optoelectronic semiconductor chip in places; and
particles of a light-scattering and/or light-reflecting material, wherein
the bottom of the semiconductor layer sequence is at least in places free of the light-transmissive encapsulating material, and
the particles cover the bottom of the semiconductor layer sequence and an outer face of the encapsulating material in places.

19. The optoelectronic semiconductor component according to claim 18, wherein the particles are fixed by a material with good gap penetration on the bottom of the semiconductor layer sequence and the outer face of the encapsulating material, wherein the material with good gap penetration is in places in direct contact with at least some of the particles and the encapsulating material.

20. The optoelectronic semiconductor component according to claim 19, wherein the particles form a layer, the material with good gap penetration penetrates completely through the layer of particles, and the encapsulating material differs from the material with good gap penetration.

21. The optoelectronic semiconductor component according to claim 18, wherein an electrically conductive material is arranged on the side remote from the optoelectronic semiconductor chip of the particles and/or of the material with good gap penetration, and the electrically conductive material electrically conductively contacts the electrical connection points of the optoelectronic semiconductor chip.

22. The optoelectronic semiconductor component according to claim 21, wherein the electrically conductive material reflects light and, together with the particles and optionally with the material with good gap penetration, has a reflectivity for light of at least 95%.

23. The optoelectronic semiconductor component according to claim 21, wherein an ESD-protective layer on the bottom remote from the optoelectronic semiconductor chip of the electrically conductive material electrically conductively contacts the electrically conductive material.

24. The optoelectronic semiconductor component according to claim 18, wherein the light-transmissive encapsulating material has singulation traces.

25. A method of producing an optoelectronic semiconductor component comprising:
providing an optoelectronic semiconductor chip comprising a light-transmissive carrier, a semiconductor layer sequence on the light-transmissive carrier and electrical connection points on a bottom portion remote from the light-transmissive carrier of the semiconductor layer sequence;
applying the optoelectronic semiconductor chip onto an auxiliary carrier such that the electrical connection points face the auxiliary carrier;
encapsulating the optoelectronic semiconductor chip in a light-transmissive encapsulating material, wherein the light-transmissive encapsulating material on the bottom portion thereof adjoins the auxiliary carrier;
detaching the auxiliary carrier and exposing the bottom portion of the semiconductor layer sequence and the light-transmissive encapsulating material; and
applying particles of a light-scattering and/or light-reflecting material to the exposed bottom portion of the semiconductor layer sequence and the encapsulating material.

26. The method according to claim 25, wherein the particles are fixed on the bottom portion of the semiconductor layer sequence and the encapsulating material by application of a material with good gap penetration.

27. The method according to claim 26, wherein the material with good gap penetration may be in direct contact in places with at least some of the particles and the encapsulating material.

28. The method according to claim 25, wherein, after application of the particles or after application of the material with a good gap penetration, an electrically conductive material is applied to the bottom remote from the optoelectronic semiconductor chip of the particles and/or of the material with a good gap penetration, and the electrically conductive material is brought into electrically conductive contact with the electrical connection points of the optoelectronic semiconductor chip.

29. The method according to claim 25, wherein the particles are deposited by electrophoresis in an electrophoresis bath.

30. The method according to claim 25, wherein
prior to deposition of the particles, an electrically conductive auxiliary layer is applied to the exposed bottom of the semiconductor layer sequence and the encapsulating material, and the auxiliary layer forms at least in part a salt with a protic reactant,
at least the electrically conductive auxiliary layer is introduced into the protic reactant such that the electrically conductive auxiliary layer at least in part forms a salt with the protic reactant, and
the salt is at least partially washed out.

31. The method according to claim 25, wherein, prior to encapsulation with the light-transmissive encapsulating material, an ESD-protective element for the optoelectronic semiconductor chip is applied to the auxiliary carrier.

32. The method according to claim 25, wherein the auxiliary carrier comprises at least one well and at least one optoelectronic semiconductor chip is introduced into the at least one well.

33. The method according to claim 32, wherein at least one ESD-protective element is introduced into the well.

34. The method according to claim 25, wherein an ESD-protective layer on the bottom remote from the optoelectronic semiconductor chip of the electrically conductive material electrically conductively contacts the electrically conductive material.

35. An optoelectronic semiconductor component comprising:
an optoelectronic semiconductor chip comprising a light-transmissive carrier, a semiconductor layer sequence on the light-transmissive carrier and electrical connection points on a bottom portion remote from the light-transmissive carrier of the semiconductor layer sequence;
a light-transmissive encapsulating material that encloses the optoelectronic semiconductor chip in places; and
particles, wherein
the bottom portion of the semiconductor layer sequence is at least in places free of the light-transmissive encapsulating material,
the particles cover the bottom portion of the semiconductor layer sequence and an outer face of the encapsulating material in places,
the particles are fixed by a material with good gap penetration on the bottom portion of the semiconductor layer sequence and the outer face of the encapsulating material, wherein the material with good gap penetration is in places in direct contact with at least some of the particles and the encapsulating material,
the particles form a layer, and the material with good gap penetration penetrates completely through the layer of particles and the encapsulating material differs from the material with good gap penetration.

36. The optoelectronic semiconductor component according to claim 35, wherein the particles consist of a light-scattering and/or light-reflecting material.
